(19) United States
(12) Patent Application Publication
(10) Pub. No.: US 2011/0128716 A1
(43) Pub. Date: Jun. 2, 2011

(54) DISPLAY DEVICE

(75) Inventor: HAI-QING ZHOU, Shenzhen City (CN)

(73) Assignees: HONG FU JIN PRECISION INDUSTRY (ShenZhen) CO., LTD, Shenzhen City (CN); HON HAI PRECISION INDUSTRY CO., LTD., Tu-Cheng (TW)

(21) Appl. No.: 12/698,149

(22) Filed: Feb. 2, 2010

(30) Foreign Application Priority Data
Nov. 27, 2009 (CN) 200910310546.6

(51) Int. Cl. H05K 7/00

(52) U.S. Cl. 361/829

(57) ABSTRACT

A display includes a screen mounted in a frame, and a protective cover covering on the screen. The frame includes two first sidewalls respectively located on the left and right sides of the screen, and two second sidewalls respectively disposed at top and bottom sides of the screen. The protective cover includes a transparent base plate, two fixing plates formed respectively at left and right sides of the base plate, and an adjoining plate formed at a top side of the base plate. The two fixing plates are fixed on the two first sidewalls of the frame, respectively. The base plate is covered on the screen. The adjoining plate abuts on the second sidewall at the top side of the screen.

### BACKGROUND

1. Technical Field

The present disclosure generally relates to display devices, and more particularly, to a display device with protective cover.

2. Description of Related Art

A display device of a computer generally includes a frame and a screen mounted in the frame. To achieve good display quality, the screen is usually coated with a layer of optical film. Exposure to hazardous environmental elements such as dust and other abrasive stain or dirt adversely affects display quality of the screen. The optical film coating on the screen is gradually eroded upon cleaning until finally, the good display quality of the screen is gone.

Therefore, a display device is desired to overcome the above-described shortcoming.

### BRIEF DESCRIPTION OF THE DRAWINGS

FIG. 1 is an assembled, isometric view of a display device in accordance with an embodiment of the present disclosure.

FIG. 2 is an exploded, isometric view of the display device of FIG. 1.

FIG. 3 is an enlarged view of the circled portion III of FIG. 2.

### DETAILED DESCRIPTION

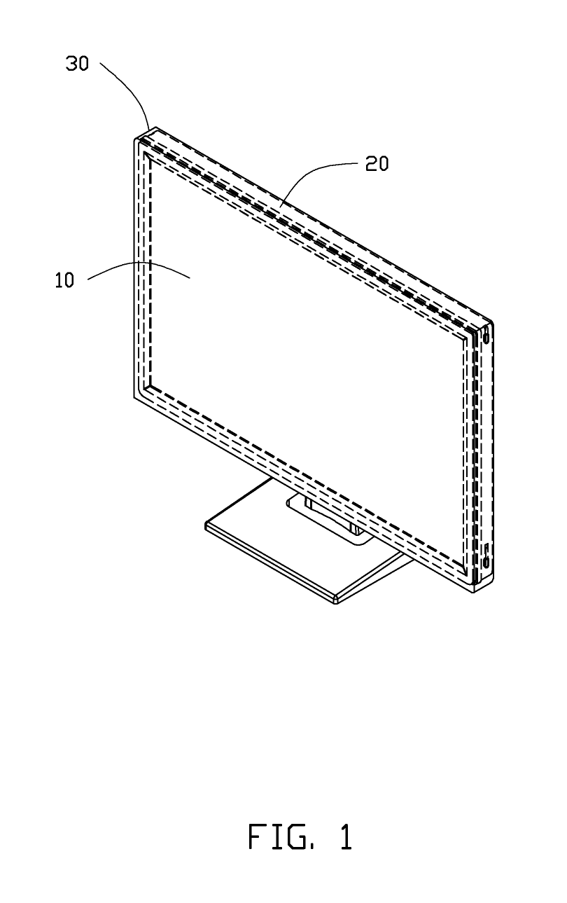

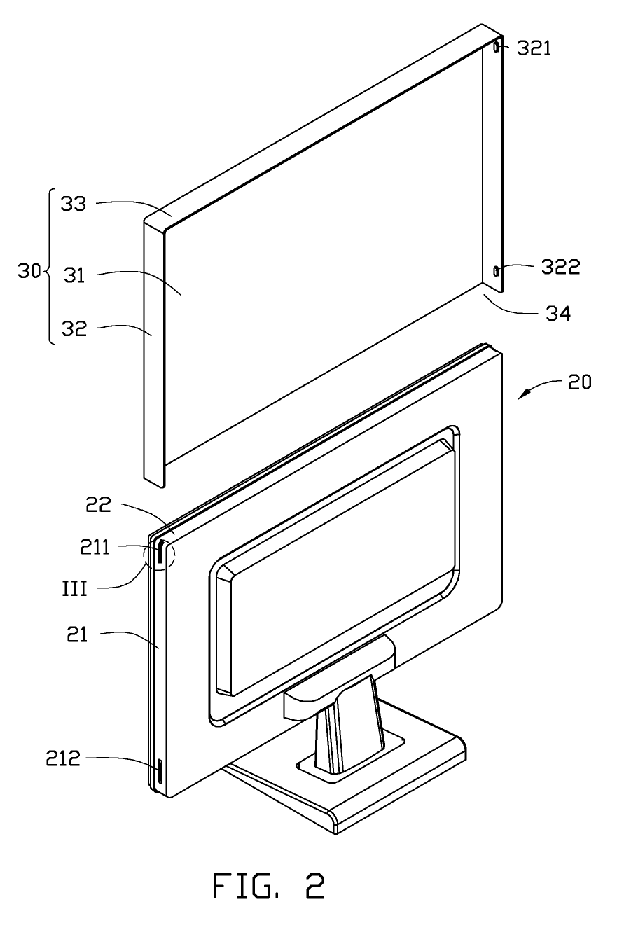

FIG. 1 and FIG. 2 show a display device in accordance with an embodiment of the present disclosure. The display device includes a screen 10 mounted in a frame 20, and a protective cover 30 shielding the screen 10.

The screen 10 is substantially rectangular and capable of displaying multimedia contents. In this embodiment, the screen 10 is a liquid crystal display (LCD).

The frame 20 includes two first sidewalls 21 located respectively at left and right sides of the screen 10, and two second sidewalls 22 located respectively at top and bottom sides of the screen 10. The first sidewalls 21 are perpendicular to the second sidewalls 22. The first sidewalls 21 and the second sidewalls 22 are alternately connected with each other end to end to cooperatively form a periphery of the frame 20. Each of the two first sidewalls 21 of the frame 20 defines a first slot 211 at a top thereof and a second slot 212 at a bottom thereof. The first slot 211 and the second slot 212 are elongated and extend vertically along an extension direction of the first sidewall 21.

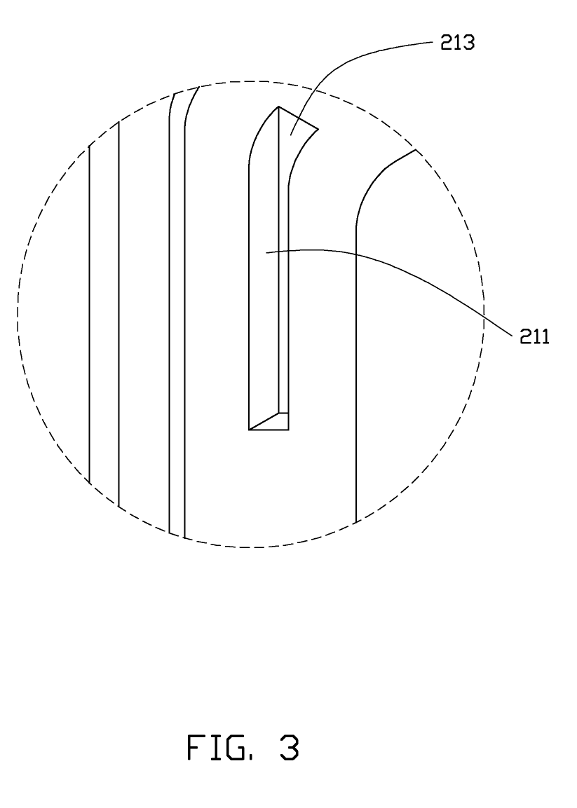

Referring also to FIG. 3, the first slot 211 defines an entrance 213 at a top thereof extending through the second sidewall 22 at the top side of the screen 10. The entrances 213 of the first slots 211 of the two first sidewalls 21 are located at a same level.

Referring back to FIG. 2, the protective cover 30 is substantially rectangular and made of transparent material. In this embodiment, the protective cover 30 is made of polymethylmethacrylate (PMMA). The protective cover 30 includes a base plate 31, two fixing plates 32 formed respectively at left and right sides of the base plate 31, and an adjoining plate 33 formed at a top side of the base plate 31. The two fixing plates 32 and the adjoining plate 33 extend outwardly and perpendicularly from the left side, the right side, and the top side of the base plate 31 respectively. An opening 34 is formed at a bottom side of the base plate 31 between the two fixing plates 32. Each of the fixing plates 32 faces a corresponding first sidewall 21 of the frame 20, and is mounted on the corresponding first sidewall 21. A first nub 321 extends inwardly from atop inner surface of each of the two fixing plates 32. A second nub 322 extends inwardly from a bottom inner surface of each of the two fixing plates 32. The first nub 321 and the second nub 322 are strip-shaped and extend along an extension direction of the fixing plate 32. The adjoining plate 33 faces the second sidewall 22 at the top side of the screen 10. A distance between the fixing plates 32 is the same as a width of the frame 20.

In assembling the protective cover 30 onto the frame 20 of the display device, the protective cover 30 is placed in front of the screen 10, with the adjoining plate 33 being located above the second sidewall 22 of the frame 20 at the top side of the screen 10. The first nubs 321 of the protective cover 30 are located above the first slots 211 of the frame 20. The second nubs 322 of the protective cover 30 are located above the second slots 212 of the frame 20. The fixing plates 32 of the protective cover 30 are expanded outwards by an operator to cause the distance between the fixing plates 32 to be a little greater than the width of the frame 20, and the protective cover 30 is pushed towards the screen 10 to cause the frame 20 to enter a space defined in the protective cover 30. At this stage, the first nubs 321 of the protective cover 30 is located slightly above and aligned with the first slots 211 of the frame 20. The protective cover 30 is pushed downwardly to cause the two first nubs 321 of the protective cover 30 to enter the first slots 211 of the frame 20 via the entrances 213 of the first slots 211. Simultaneously, the operator releases the fixing plates 32 of the protective cover 30, so that the two second nubs 322 of the protective cover 30 respectively engage in the two second slots 212 of the frame 20. At this time, the adjoining plate 33 of the protective cover 30 abuts against the second sidewall 22 at the top side of the screen 10, and the base plate 31 of the protective cover 30 covers the screen 10 in front of the display device.

When the display device is exposed to environmental elements, the protective cover 30 prevents contaminants from fouling the frame 20 and the screen 10. Users of the display device can clean the protective cover 30, instead of directly cleaning the screen 10 and the frame 20, without risk of abrasion or damage to the optical film coating on the screen 10. Thus, good display quality of the screen 10 is maintained for a long-term and if needed, the protective cover 30 is easily replaced.

It is to be understood, however, that even though numerous characteristics and advantages of the disclosure have been set forth in the foregoing description, together with details of the structures and functions of the embodiment(s), the disclosure is illustrative only, and changes may be made in detail, especially in matters of shape, size, and arrangement of parts within the principles of the invention to the full extent indicated by the broad general meaning of the terms in which the appended claims are expressed.

What is claimed is:

1. A display device, comprising:
a frame;
a screen, the screen being mounted in the frame, the frame comprising two first sidewalls located respectively at left and right sides of the screen, and two second sidewalls located respectively at top and bottom sides of the screen; and
a protective cover comprising a transparent base plate covering the screen, two fixing plates respectively mounted on the two first sidewalls of the frame, and an adjoining plate abutting on the second sidewall at the top side of the screen.

2. The display device of claim 1, wherein each of the first sidewalls defines a first slot therein, each of the fixing plates protrudes a first nub corresponding to the first slot, and the first nub of each of the fixing plates is engaged in the first slot of a corresponding first sidewall.

3. The display device of claim 2, wherein each of the first sidewalls further defines a second slot therein, each of the fixing plates further protrudes a second nub corresponding to the second slot, and the second nub of each of the fixing plates is engaged in the second slot of a corresponding first sidewall.

4. The display device of claim 3, wherein the first slot and the second slot each are elongated along the first sidewalls, and the first and second nubs each are strip-shaped along the fixing plates.

5. The display device of claim 4, wherein the first slot and the second slot of each first sidewall of the frame are respectively located at top and bottom ends of the first sidewall of the frame, a top of the first slot defines an entrance extending through the second sidewall at the top side of the screen, and the first nub of the protective cover enters the first slot via the entrance.

6. The display device of claim 5, wherein the entrances of the first slots are located at a same level.
